(19) United States
(12) Patent Application Publication
(10) Pub. No.: US 2018/0342633 A1
(43) Pub. Date: Nov. 29, 2018

(54) COMPOUND SEMICONDUCTOR SOLAR CELL

(71) Applicant: LG ELECTRONICS INC., Seoul (KR)

(72) Inventors: Wonseok CHOI, Seoul (KR); Gunho KIM, Seoul (KR)

(73) Assignee: LG ELECTRONICS INC., Seoul (KR)

(21) Appl. No.: 15/988,478

(22) Filed: May 24, 2018

(30) Foreign Application Priority Data
May 25, 2017 (KR) 10-2017-0064693

(51) Int. Cl. H01L 31/0304; H01L 31/0224

(52) U.S. Cl. CPC H01L 31/03046; H01L 31/03042; H01L 31/022433; H01L 31/022441

(57) ABSTRACT

There is provided a compound semiconductor solar cell, comprising: a top cell including a compound semiconductor layer; a front electrode located on a front surface of the top cell and including a plurality of finger electrodes; and a back electrode disposed on a back surface of the top cell, wherein the top cell including a first window layer positioned on a light receiving surface of the top cell, a first base layer containing impurities of a first conductive type and located on a back surface of the first window layer, and a first emitter layer containing impurities of a second conductive type opposite the first conductive type and located on a back surface of the first base layer to form a p-n junction with the first base layer, wherein the first base layer includes a first layer having a first electrical conductivity and a second layer having a second electrical conductivity different from the first electrical conductivity, and wherein an interval between the second layer and the first emitter layer is larger than an interval between the first layer and the first emitter layer. The second electrical conductivity of the second layer may be higher than the first electrical conductivity of the first layer.

### CROSS-REFERENCE TO RELATED APPLICATION

This application claims priority to and the benefit of Korean Patent Application No. 10-2017-0064693 filed in the Korean Intellectual Property Office on May 25, 2017, the entire contents of which are incorporated herein by reference.

### BACKGROUND OF THE INVENTION

### Field of the Invention

The present disclosure relates to a compound semiconductor solar cell, and more particularly to a compound semiconductor solar cell having a rear emitter structure in which an emitter layer is disposed on the opposite side of a light receiving surface.

### Description of the Related Art

A compound semiconductor solar cell includes a compound semiconductor layer formed of various layers using a III-V compound semiconductor such as gallium arsenide (GaAs), indium phosphide (InP), gallium aluminum arsenide (GaAlAs) and gallium indium arsenide (GaInAs), a II-VI compound semiconductor such as cadmium sulfide (CdS), cadmium telluride (CdTe) and zinc sulfide (ZnS), a I-III-VI compound semiconductor such as copper indium selenide (CuInSe₂), and the like.

Among them, a compound semiconductor solar cell having a compound semiconductor layer formed of a III-V compound semiconductor is divided a single junction structure including only one cell, that is, a top cell, and a multi-junction structure including at least two cells, that is, a top cell/(a middle cell)/a bottom cell. In recent years, a rear emitter structure compound semiconductor solar cell in which an emitter layer for collecting minor carriers formed in the base layer is disposed on the opposite side of the light receiving surface, is being developed.

However, since a front electrode located on the light receiving surface of the compound semiconductor solar cell is formed as a grid pattern in order to secure the light receiving area, in a compound semiconductor solar cell having the rear emitter structure, a lateral path, which means a path where majority carriers formed in the base layer having a higher resistance than the emitter layer move to the front electrode, increases. Therefore, a fill factor is lowered, and the efficiency of the compound semiconductor solar cell is deteriorated.

### SUMMARY OF THE INVENTION

The present disclosure provides a compound semiconductor solar cell having a rear emitter structure and capable of preventing a decrease in fill factor and a decrease in efficiency.

In one aspect, there is provided a compound semiconductor solar cell, comprising: a top cell including a compound semiconductor layer; a front electrode located on a front surface of the top cell and including a plurality of finger electrodes; and a back electrode disposed on a back surface of the top cell, wherein the top cell including a first window layer positioned on a light receiving surface of the top cell, a first base layer containing impurities of a first conductive type and located on a back surface of the first window layer, and a first emitter layer containing impurities of a second conductive type opposite the first conductive type and located on a back surface of the first base layer to form a p-n junction with the first base layer, wherein the first base layer includes a first layer having a first electrical conductivity and a second layer having a second electrical conductivity different from the first electrical conductivity, and wherein an interval between the second layer and the first emitter layer is larger than an interval between the first layer and the first emitter layer.

The second electrical conductivity of the second layer may be higher than the first electrical conductivity of the first layer.

In order to make the second electrical conductivity of the second layer higher than the electrical conductivity of the first layer, the first layer may be doped with a first doping concentration and the second layer may be doped with a second doping concentration higher than the first doping concentration.

At this time, in the first layer, the first doping concentration may be uniform in the thickness direction of the first layer, or may increases as the distance from the first emitter layer in the thickness direction of the first layer increases.

The first doping concentration may be equal to or less than 5e17/cm³ and the second doping concentration may be 5e17/cm³ to 1e18/cm³. Preferably, the first doping concentration may be 5e16/cm³ to 5e17/cm³.

In the second layer, the second doping concentration may be uniform in the thickness direction of the second layer, or may increase as the distance from the first emitter layer in the thickness direction of the second layer increases.

When the first doping concentration and/or the second doping concentration varies in the thickness direction of corresponding layer, the first doping concentration and/or the second doping concentration may be changed into a step type, a logarithm type, exponential type, or linear type.

The second layer may be formed to be thinner than the first layer.

In one aspect, the first layer may be formed to a thickness of 1 μm to 3 μm, and the second layer may be formed to a thickness of 50 nm to 1 μm.

At this time, each of the first and second layers may be formed of a GaAs-based compound semiconductor.

The second layer may be formed of Al_{0.3}Ga_{0.7}As containing aluminum (Al), and may have a higher band gap than the first layer.

When the second layer contains aluminum, in the second layer, an aluminum content of the second layer may be uniform in the thickness direction of the second layer, or may increases as the distance from the first emitter layer in the thickness direction of the second layer increases.

When the aluminum content varies in the thickness direction of the second layer, the aluminum content of the second layer may be changed into a step type, a logarithm type, exponential type, or linear type.

The top cell may further comprise a first back surface field layer positioned on a back surface of the first emitter layer.

In another aspect, the first layer may be formed to a thickness of 300 nm to 3 μm, and the second layer may be formed to a thickness of 50 nm to 500 nm.

At this time, each of the first and second layers may be formed of GaInP-based compound semiconductors, and the second layer may be formed of Al_{0.25}Ga_{0.25}In_{0.5}P containing aluminum (Al). The second layer may have a higher band gap than the first layer.

When the second layer contains aluminum, in the second layer, an aluminum content of the second layer may be uniform in the thickness direction of the second layer, or may increases as the distance from the first emitter layer in the thickness direction of the second layer increases.

When the aluminum content varies in the thickness direction of the second layer, the aluminum content of the second layer may be changed into a step type, a logarithm type, exponential type, or linear type.

The compound semiconductor solar cell may further comprise at least one cell formed between the top cell and the back electrode and formed of a compound semiconductor.

The at least one cell may comprise a window layer, a base layer and an emitter layer sequentially stacked from the top cell toward the back electrode, and the base layer may be formed of single layer doped with the first doping concentration. In the base layer, the first doping concentration may be uniform in the thickness direction of the base layer, or may increase as the distance from the emitter layer in the thickness direction of the base layer increases.

The at least one cell may further comprise a back surface field layer positioned on a back surface of the emitter layer.

The compound semiconductor solar cell may further comprise a tunnel junction layer positioned between the different cells.

The at least one cell may be formed of any one selected from a GaAs-based compound semiconductor, a GaInAs-based compound semiconductor, an AlGaAs-based compound semiconductor, an AlGaInAs-based compound semiconductor, and a Ge-based compound semiconductor.

In the compound semiconductor solar cell according to the present invention, the first base layer of the top cell positioned on the light receiving surface has the first layer having the first electrical conductivity and the second layer having the second electrical conductivity higher than the first electrical conductivity, and the second layer is located at a portion adjacent to the front electrode as compared to the first layer. Therefore, since the resistance on the lateral path, which means a path where majority carriers formed in the base layer having a higher resistance than the emitter layer move to the front electrode, is reduced, the decrease of the fill factor can be prevented.

If the second layer contains aluminum and has a higher band gap than the first layer, the probability of charge recombination in the second layer decreases. Therefore, the open-circuit voltage Voc can be prevented from lowering.

Therefore, the efficiency of the compound semiconductor solar cell having the rear emitter structure can be prevented from being lowered.

### BRIEF DESCRIPTION OF THE DRAWINGS

FIG. 1 is a cross-sectional view of a single junction compound semiconductor solar cell according to a first embodiment of the present invention.

FIG. 2 is a graph showing electrical characteristics of the compound semiconductor solar cell shown in FIG. 1.

FIG. 3 is a cross-sectional view of a compound semiconductor solar cell having a double junction structure according to a second embodiment of the present invention.

FIG. 4 is a cross-sectional view of a single junction structure compound semiconductor solar cell according to a third embodiment of the present invention.

FIG. 5 is a cross-sectional view of a double junction structure compound semiconductor solar cell according to a fourth embodiment of the present invention.

### DETAILED DESCRIPTION OF THE EMBODIMENTS

Reference will now be made in detail embodiments of the disclosure examples of which are illustrated in the accompanying drawings. Since the present disclosure may be modified in various ways and may have various forms, specific embodiments are illustrated in the drawings and are described in detail in the present specification. However, it should be understood that the present disclosure are not limited to specific disclosed embodiments, but include all modifications, equivalents and substitutes included within the spirit and technical scope of the present disclosure.

The terms “first”, “second”, etc. may be used to describe various components, but the components are not limited by such terms. The terms are used only for the purpose of distinguishing one component from other components.

For example, a first component may be designated as a second component, and a second component may be designated as a first component without departing from the scope of the present disclosure.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no component exists between them.

The terms used in the present application are used to describe only specific embodiments or examples, and are not intended to limit the present disclosure. A singular expression can include a plural expression as long as it does not have an apparently different meaning in context.

In the present application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the present disclosure pertains.

The terms defined in a generally used dictionary must be understood to have meanings identical to those used in the context of a related art, and are not to be construed to have ideal or excessively formal meanings unless they are obviously specified in the present application.

The following example embodiments of the present disclosure are provided to those skilled in the art in order to describe the present disclosure more completely. Accordingly, shapes and sizes of elements shown in the drawings may be exaggerated for clarity.

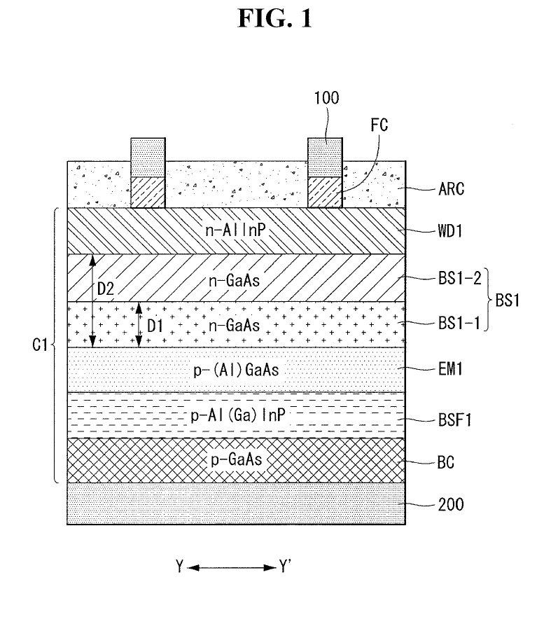

Hereinafter, embodiments of the disclosure are described with reference to FIGS. 1 to 5.

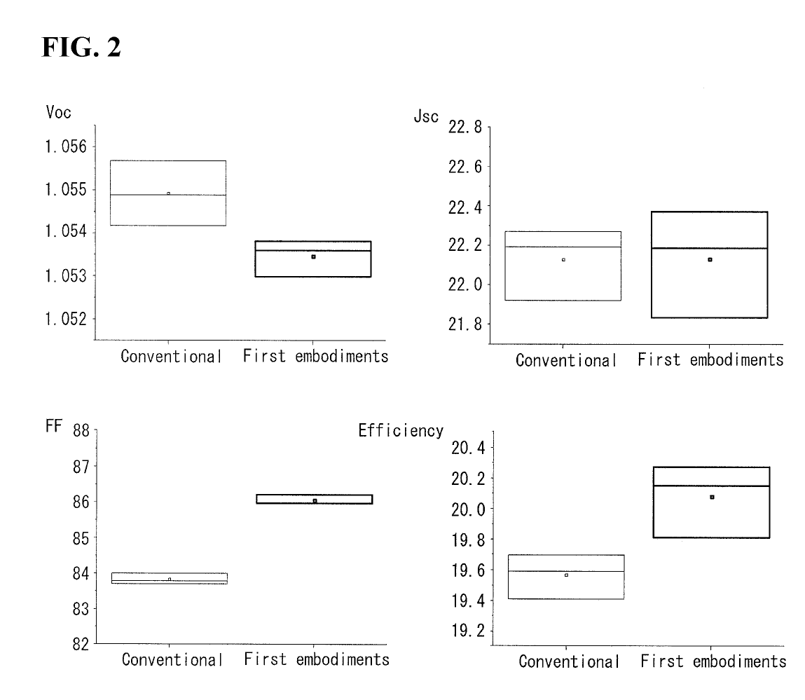

FIG. 1 is a cross-sectional view of a single junction compound semiconductor solar cell according to a first embodiment of the present invention. FIG. 2 is a graph showing electrical characteristics of the compound semiconductor solar cell shown in FIG. 1.

The compound semiconductor solar cell according to the first embodiment of the present invention is a solar cell having a single junction structure including only one cell, that is, the top cell C1. The top cell C1 has a compound semiconductor layer formed of a III-VI group compound semiconductor. The compound semiconductor layer may includes a first window layer WD1 positioned on a light receiving surface of the top cell C1, a first base layer BS1 positioned on a back surface of the first window layer WD1 and containing impurities of a first conductivity type, a first emitter layer EM1 positioned on a back surface of the first emitter layer BS1 and containing impurities of a second conductivity type opposite the first conductive type, a back surface field layer BSF1 positioned on a back surface of the first emitter layer, a front contact layer FC positioned on a front surface of the first window layer WD1 and a back contact layer BC positioned on a back surface of the first back surface field layer BSF1.

The compound semiconductor solar cell of the first embodiment further includes a grid-shaped front electrode 100 positioned on a front surface of the front contact layer FC and a sheet-shaped back electrode 200 positioned on a back surface of the back contact layer BC.

The first base layer BS1 comprises n type impurities and includes a first layer BS1-1 having a first electrical conductivity and a second layer BS1-2 having a second electrical conductivity higher than the first electrical conductivity of the first layer BS1-1. An interval D1 between the second layer BS1-2 and the first emitter layer EM1 is formed to be larger than an interval D2 between the first layer BS1-1 and the first emitter layer EM1.

Here, the interval D1 means a distance between a front surface of the first layer BS1-1 and the first emitter layer EM1, and the interval D2 means a distance between a front surface of the second layer BS1-2 and the first emitter layer EM1.

Thus, the second layer BS1-2 may directly contact the first window layer WD1, and the first layer BS1-1 may directly contact the first emitter layer EM1.

In order to make the second electrical conductivity of the second layer BS1 -2 higher than the electrical conductivity of the first layer BS1-1, the first layer BS1-1 may be doped with a first doping concentration and the second layer BS1-2 may be doped with a second doping concentration higher than the first doping concentration.

The first doping concentration may be equal to or less than 5e17/cm³ and the second doping concentration may be 5e17/cm³ to 1e18/cm³. Preferably, the first doping concentration may be 5e16/cm³ to 5e17/cm³.

The first doping concentration and/or the second doping concentration may be uniform in the thickness direction of the corresponding layer, or may increase as the distance from the first emitter layer EM1 in the thickness direction of the corresponding layer increases.

When the first doping concentration and/or the second doping concentration varies in the thickness direction of corresponding layer, the first doping concentration and/or the second doping concentration may be changed into a step type, a logarithm type, exponential type, or linear type.

The second layer BS1-2 may be formed to be thinner than the first layer BS1-1.

In one aspect, the first layer BS1-1 may be formed to a thickness of 1 μm to 3 μm, and the second layer BS1-2 may be formed to a thickness of 50 nm to 1 μm.

Here, the thickness of the first layer BS1-1 may be equal to the interval D1, and the thickness of the second layer BS1-2 may be equal to the interval D2.

The first emitter layer EM1 contains impurities of the second conductivity type opposite the first conductivity type of the first base layer BS1 and forms a p-n junction with the first base layer BS1. Here, the impurities of the second conductivity type may be p-type impurities.

Each of the first layer BS1-1 and the second layer BS1-2 is formed of a GaAs-based compound semiconductor.

For example, the first layer BS1-1 and the second layer BS1-2 of the first base layer BS1 are each formed of n-GaAs, and the first emitter layer EM1 is formed of p-(Al) GaAs.

The p-type impurities doped in the first emitter layer EM1 may be selected from carbon (C), magnesium (Mg), zinc (Zn), or a combination thereof. The n-type impurities doped in the first base layer BS1 may be selected from silicon (Si), selenium (Se), tellurium (Te), or a combination thereof.

The first base layer BS1 is positioned on a region adjacent to the front electrode 100 and the first emitter layer EM1 is positioned on a region adjacent to the back electrode 200. Thus, the compound semiconductor solar cell of the present invention has a rear emitter structure.

According to the configuration, the electron-hole pairs generated by the light incident on the first base layer BS 1 are separated into electrons and holes by the internal potential difference formed by the p-n junction of the first emitter layer EM1 and the first base layer BS1 so that electrons move toward the n-type semiconductor layer and holes move toward the p-type semiconductor layer.

Thus, holes which are minority carriers generated inside the first base layer BS1 move to the back electrode 200 through the back contact layer BC, and electrons which are majority carriers generated in the first base layer BS1 move to the front electrode 100 through the first window layer WD1 and the front contact layer FC.

When the top cell C1 further includes a first back surface field layer BSF1, the first back surface field layer BSF1 has the same conductivity as the first emitter layer EM1. Thus, the first back surface field layer BSF1 may be formed of p-Al(Ga)InP.

In order to effectively block the movement of the charge (holes or electrons) to be moved toward the front electrode 100 toward the back electrode 200, the first back surface field layer BSF1 is formed entirely on the back surface of the first emitter layer EM1.

The first window layer WD1 is formed between the first base layer BS1 and the front electrode 100 and passivates the front surface of the first base layer BS1.

Therefore, when majority carriers (electrons) move to the surface of the first base layer BS1, the first window layer WD1 prevents the majority carriers from recombining on the surface of the first base layer BS1.

Since the first window layer WD1 is disposed on the front surface (i.e., light incident surface) of the first base layer BS1, in order to prevent light incident on the first base layer BS1 from being absorbed, the first window layer WD1 may have an energy band gap higher than the energy band gap of the first base layer BS1.

Therefore, the first window layer WD1 may be formed of n-AlInP having a band gap of approximately 2.3 eV.

The antireflection layer ARC may be disposed in a region other than the region where the front electrode 100 and/or the front contact layer FC are located in the front surface of the first window layer WD1.

Alternatively, the antireflection layer may be disposed on the front contact layer FC and the front electrode 100 as well as the exposed first window layer WD1.

The compound semiconductor solar cell may further include At least one bus bar electrodes each physically connecting a plurality of front electrodes 100, and the at least one bus bar electrodes may be exposed to the outside without being covered by the antireflection layer.

The antireflection layer may include magnesium fluoride, zinc sulfide, titanium oxide, silicon oxide, a derivative thereof, or a combination thereof.

The front electrode 100 may be formed to extend in a first direction and may be spaced apart at regular intervals along a second direction Y-Y′ orthogonal to the first direction.

The front electrode 100 may be formed to include an electrically conductive material and may include at least one of gold (Au), germanium (Ge), and nickel (Ni).

The front contact layer FC positioned between the first window layer WD1 and the front electrode 100 is formed by doping the n-type impurities with a doping concentration higher than the doping concentration of the first base layer BS1 into the III-V compound semiconductor. For example, the front contact layer FC may be formed of n+− GaAs.

The front contact layer FC forms an ohmic contact between the first window layer WD1 and the front electrode 100. That is, when the front electrode 100 directly contacts the first window layer WD1, the ohmic contact between the front electrode 100 and the base layer BS1 is not well formed because the doping concentration of the first window layer WD1 is low. Therefore, the carrier moved to the first window layer WD1 cannot move to the front electrode 100 and may be destroyed.

However, when the front contact layer FC is formed between the front electrode 100 and the first window layer WD1, since the front contact layer FC forms an ohmic contact with the front electrode 100, the carrier is smoothly moved and the short circuit current density Jsc of the compound semiconductor solar cell increases. Thus, the efficiency of the solar cell can be further improved.

The front contact layer FC may be formed in the same shape as the front electrode 100.

The back contact layer BC disposed on the back surface of the first back surface field layer BSF1 is entirely formed on the back surface of the first back surface field layer BSF1. The back contact layer BC may be formed by doping the p-type impurities into the III-VI group semiconductor compound. For example, the back contact layer BC may be formed of p-GaAs.

The back contact layer BC forms an ohmic contact with the back electrode 200, so that the short circuit current density Jsc of the compound semiconductor solar cell can be further improved. Thus, the efficiency of the solar cell can be further improved.

A thickness of the front contact layer FC and a thickness of the back contact layer BC may each be 100 nm to 300 nm. For example, the front contact layer FC may be formed with the thickness of 100 nm and the back contact layer BC may be formed with the thickness of 300 nm.

The back electrode 200 positioned on the back surface of the back contact layer BC may be a sheet-like conductive layer positioned entirely on the back surface of the back contact layer BC, different from the front electrode 100. That is, the back electrode 200 may be referred to as a sheet electrode located on the entire back surface of the back contact layer BC.

At this time, the back electrode 200 may be formed in the same plane as the first base layer BS1 and may be formed of at least one material selected from the group consisting of gold (Au), platinum (Pt), titanium (Ti), tungsten (W), silicon (Si), nickel (Ni), magnesium (Mg), palladium (Pd), copper (Cu), and germanium (Ge). The back electrode 200 may be formed of single layer or multi layer, and the material forming the back electrode 200 may be suitably selected according to the conductivity type of the back contact layer BC.

For example, when the back contact layer BC contains p-type impurities, the back electrode 200 may be formed any one of gold (Au), platinum/titanium (Pt/Ti), tungsten-silicon alloy (WSi), and silicon/nickel/magnesium/nickel (Si/Ni/Mg/Ni). Preferably, the back electrode 200 may be formed of gold (Au) having a low contact resistance with the p-type back contact layer BC.

If the back contact layer BC contains n-type impurities, the back electrode 200 may be formed any one of palladium/gold (Pd/Au), copper/germanium (Cu/Ge), nickel/germanium-gold alloy/nickel (Ni/GeAu/Ni), gold/titanium (Au/Ti). Preferably, the back electrode 200 may be formed of palladium/gold (Pd/Au) having a low contact resistance with the p-type back contact layer BC.

However, the material forming the back electrode 200 can be appropriately selected among the materials, and in particular, can be appropriately selected from materials having low contact resistance with the back contact layer BC.

In the compound semiconductor solar cell according to the present invention, the first base layer of the top cell positioned on the light receiving surface has the first layer having the first electrical conductivity and the second layer having the second electrical conductivity higher than the first electrical conductivity, and the second layer is located at a portion adjacent to the front electrode as compared to the first layer. Therefore, since the resistance on the lateral path, which means a path where majority carriers formed in the base layer having a higher resistance than the emitter layer move to the front electrode, is reduced, the decrease of the fill factor can be prevented.

FIG. 2 is a graph comparing electrical characteristics of the compound semiconductor solar cell of the first embodiment of the present invention with a conventional compound semiconductor solar cell. Here, the compound semiconductor solar cell of the first embodiment is a compound semiconductor solar cell having a second layer BS1-2 formed at a thickness of 180 nm with a doping concentration of 1e18/cm³, and the conventional compound semiconductor solar cell is a compound semiconductor solar cell having the first layer BS1-1 formed to a thickness of the first base layer BS1.

Referring to FIG. 2, the doping concentration of the first base layer BS1 of the compound semiconductor solar cell of the first embodiment having the second layer BS1-2 is higher than that of the base layer of the conventional compound semiconductor solar cell. Therefore, the open-circuit voltage Voc is reduced by about 2 mV as compared with the conventional compound semiconductor solar cell. However, the fill factor FF increases by more than 2% as compared with the conventional compound semiconductor solar cell, and thereby the efficiency increases by about 0.6% or more.

The compound semiconductor solar cell may be made by a method including a step of forming a sacrificial layer on one side of a mother substrate, a step of forming a compound semiconductor layer on the sacrificial layer, and a step of separating the compound semiconductor layer by using an ELO process.

Although the compound semiconductor solar cell has a single junction structure including only the top cell C1 in the above description, the compound semiconductor solar cell of the present invention may have a multi junction structure including a plurality of cells.

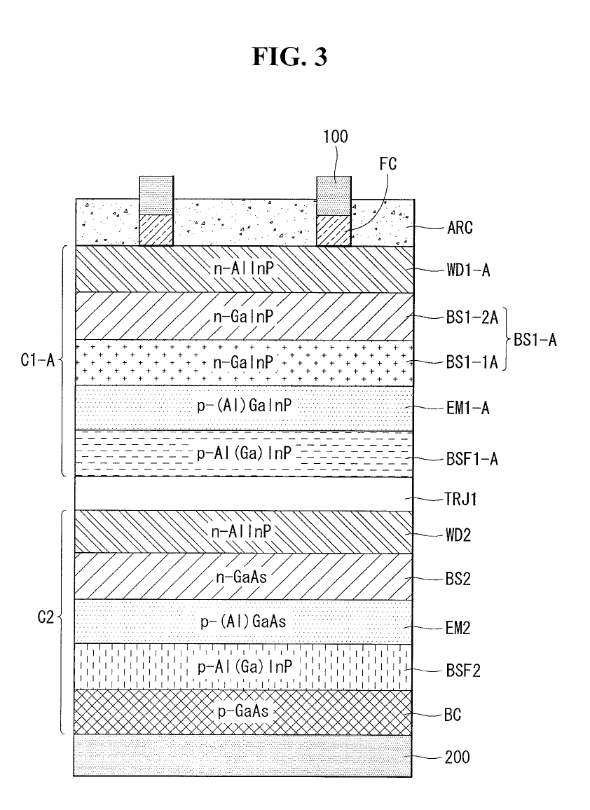

A compound semiconductor solar cell having a double junction structure among the multi junction structures will be described with reference to FIG. 3.

As shown in FIG. 3, the compound semiconductor solar cell of the second embodiment includes a top cell C1-A, a bottom cell positioned between the top cell C1-A and the back electrode 200, and a first tunnel layer TRJI positioned between the top cell C1-A and the bottom cell C2.

In the compound semiconductor solar cell of this embodiment, the basic lamination structure of the top cell C1-A is the same as that of the top cell C1 of the first embodiment. However, the compound semiconductor forming each layer of the top cell C1-A differs from the compound semiconductor forming each layer of the top cell C1 described in the first embodiment.

That is, in the double junction solar cell, the top cell C1-A absorbs light of a short wavelength band, and the bottom cell C2 absorbs light of a middle or long wavelength band of light. Thus, the top cell C1-A comprises a compound semiconductor layer formed of a GaInP-based compound semiconductor capable of absorbing light of a short wavelength band and having a band gap of approximately 1.9eV, and the bottom cell C2 comprises a compound semiconductor layer formed of a GaAs-based compound semiconductor having a band gap of approximately 1.42 eV.

Thus, the top cell C1-A of this embodiment may comprise a first base layer BS1-A, a first emitter layer EM1-A forming a p-n junction with the first base layer BS1-A and formed of p-(Al)GaInP, a first window layer WD1-A positioned on a front surface of the first base layer BS1-A and formed of n-AlInP, and a first back surface field layer BSF1-A positioned on a back surface of the first emitter layer EM1-A and formed of p-Al(Ga)InP. The first base layer BS1-A may include a first layer BS1-1A formed of n-GaInP and a second layer BS1-2A formed of the same compound semiconductor as that of the first layer and containing n-type impurities at a high concentration as compared with the first layer BS1-1A.

At this time, the first doping concentration of the first layer BS1-1A may be 5e17/cm³ or less, preferably 5e16/cm³ to 5e17/cm³, and the second concentration of the second layer BS1-2A may be 5e17/cm³ to 1e18/cm³.

The first doping concentration and/or the second doping concentration may be uniform in the thickness direction of the corresponding layer, or may increases as the distance from the first emitter layer EM1-A in the thickness direction of the corresponding layer increases.

When the first doping concentration and/or the second doping concentration varies in the thickness direction of corresponding layer, the first doping concentration and/or the second doping concentration may be changed into a step type, a logarithm type, exponential type, or linear type.

The first layer BS1-1A may be formed to a thickness of 300 nm to 3 μm, and the second layer BS1-2A may be formed to a thickness of 50 nm to 500 nm.

In the compound semiconductor solar cell of the second embodiment having a double junction structure, the bottom cell C2 basically has the same material and lamination structure as the top cell C1 of the first embodiment described above. The second base layer BS2 of bottom cell C2 is formed as a single layer different from the first base layer BS1 of the top cell C1 of the first embodiment.

That is, the bottom cell C2 of the present embodiment comprises a single layered second base layer BS2 formed of n-GaAs, a second emitter layer EM2 forming a p-n junction with the second base layer BS2 and formed of p-(Al) GaAs, a second window layer WD2 formed between the first tunnel layer TRJ1 and the second base layer BS2 and formed of n-AlInP, and a second back surface field layer BSF2 formed on a back surface of the second emitter layer EM2 and formed of p-Al(Ga)InP.

When the compound semiconductor solar cell is formed of triple junction or quadruple junction, the bottom cell may be formed of a Ge-based compound semiconductor, and a middle cell positioned between the top cell and the bottom cell may be formed of any one selected from a GaAs-based compound semiconductor, a GaInAs-based compound semiconductor, an AlGaAs-based compound semiconductor, and an AlGaInAs-based compound semiconductor.

For example, a compound semiconductor solar cell having a multi junction structure may be formed of a bottom cell (Ge)/a middle cell (Ga(In)As)/a top cell (GaInP), a bottom cell (Ge)/a middle cell (Ga(In)As)/a middle cell (AlGa(In)As)/a top cell (GaInP), or a bottom cell (Ge)/a middle cell (GaInNAs)/a middle cell (GaInAs)/a middle cell (AlGaInAs)/a top cell (GaInP).

At this time, the base layer of the remaining cells except for the top cell may be formed as a single layer like the second base layer shown in FIG. 3.

The first tunnel layer TRJ1 may comprises a first layer contacting the first back surface field layer BSF1-A and a second layer contacting the second window layer WD2. The first layer of the first tunnel layer may be formed of p+AlGaAs doped with a higher concentration of p-type impurities than the first back surface field layer BSF1-A, and the second layer of the first tunnel layer may be formed of n+GaInP doped with z higher concentration of n-type impurities than the second window layer WD2.

Since the back contact layer BC is formed for the ohmic contact of the back electrode 200, in the compound semiconductor solar cell having the double junction structure, the back contact layer BC is positioned between the second back surface field layer BSF2 and the back electrodes 200.

In the above description, the first base layers BS1 and BS1-A of the top cells C1 and C1-A further comprise the second layers BS1-2 and BS1-2A including impurities having a higher doping concentration than that of the first layers BS1-1 and BS1-1A.

If the first base layers BS1 and BS1-A include the second layers BS1-2 and BS1-2A having a high doping concentration, the probability of recombination of electrons and holes in the second layers BS1-2 and BS1-2A increases, and thus the open circuit voltage Voc may be reduced.

Therefore, in order to reduce the probability of recombination of electrons and holes in the second layers BS1-2 and BS1-2A, the second layers BS1-2 and BS1-2A may be formed to have a higher band gap energy than the first layers BS1-1 and BS1-1A.

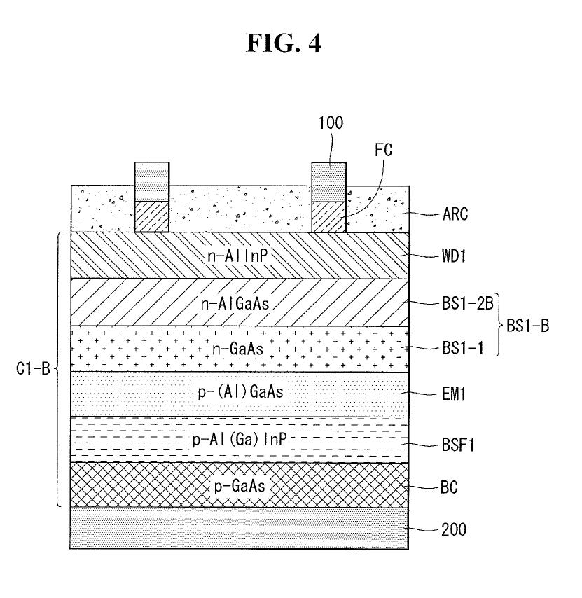

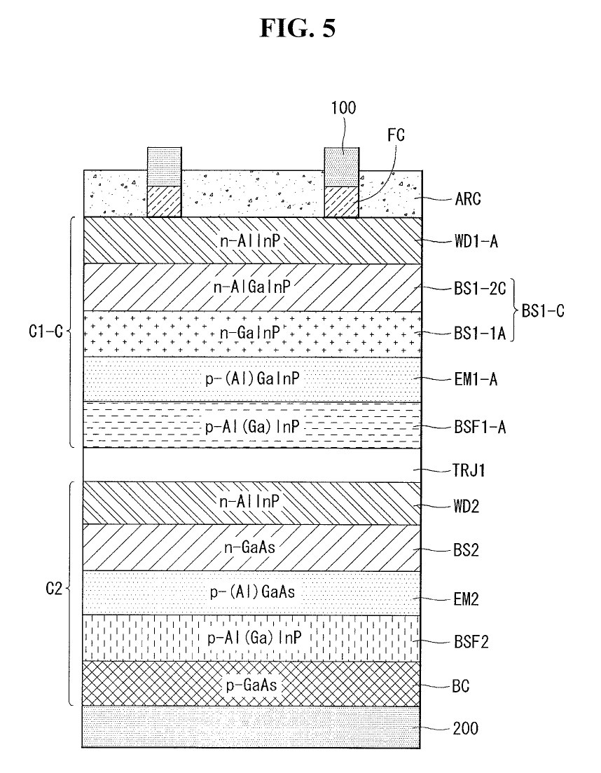

FIGS. 4 and 5 relate to an embodiment of a compound semiconductor solar cell in which the second layer has a higher band gap than the first layer.

In the compound semiconductor solar cell of FIG. 4, the second layer BS1-2 of the first base layer BS1-B of the top cell C1-B is formed of a compound semiconductor which is different from that of the second layer BS1-2 of the first base layer BS1 of the top cell C1 and the remaining components (material and lamination structure) of the compound semiconductor solar cell shown in FIG. 4 is the same as that of the compound semiconductor solar cell shown in FIG. 1. Therefore, the same reference numerals are given to the same constituent elements as those shown in FIG. 1, and a detailed description thereof will be omitted.

In the compound semiconductor solar cell of FIG. 5, the second layer BS1-2C of the first base layer BS1-C of the top cell C1-C is formed of a compound semiconductor which is different from that of the second layer BS1-2A of the first base layer BS1-A of the top cell C1-A and the remaining components (material and lamination structure) of the compound semiconductor solar cell shown in FIG. 5 is the same as that of the compound semiconductor solar cell shown in FIG. 3. Therefore, the same reference numerals are given to the same constituent elements as those shown in FIG. 1, and a detailed description thereof will be omitted

In the compound semiconductor solar cell having the single junction structure shown in FIG. 4 and the compound semiconductor solar cell having the double junction structure shown in FIG. 5, the second layers BS1-2B and BS1-2C of the first base layers BS1-B and BS1-C each include aluminum, which is one of the materials capable of increasing the band gap of the layer.

Therefore, the second layer BS1-2B of the first base layer BS1-B of the compound semiconductor solar cell shown in FIG. 4 may be formed of n-AlGaAs, particularly Al_{0.3}Ga_{0.7}As, and the second layer BS1-2C of the first base layer BS1-C of the compound semiconductor solar cell shown in FIG. 5 may be formed of n-AlGaInP, particularly Al_{0.25}Ga_{0.25}In_{0.5}P.

The aluminum contents of the second layers BS1-2B and BS1-2C may be uniform in the thickness direction of the second layers BS1-2B and BS1-2C, or may increases as the distance from the first emitter layer in the thickness direction of the second layers BS1-2B and BS1-2C increases.

When the aluminum content varies in the thickness direction of the second layers BS1-2B and BS1-2C, the aluminum content of the second layers BS1-2B and BS1-2C may be changed into a step type, a logarithm type, exponential type, or linear type.

Thus, when the second layers BS1-2B and BS1-2C of the first base layers BS1-B and BS1-C each contain aluminum, band gaps of the second layers BS1-2B and BS1-2C increase. Thus, the probability of electrons and holes recombining in the second layers BS1-2B, BS1-2C decreases. Therefore, the decrease of the open circuit voltage can be suppressed.

What is claimed is:

1. A compound semiconductor solar cell, comprising:
a top cell including a compound semiconductor layer;
a front electrode located on a front surface of the top cell and including a plurality of finger electrodes; and
a back electrode disposed on a back surface of the top cell,
wherein the top cell including a first window layer positioned on a light receiving surface of the top cell, a first base layer containing impurities of a first conductive type and located on a back surface of the first window layer, and a first emitter layer containing impurities of a second conductive type opposite the first conductive type and located on a back surface of the first base layer to form a p-n junction with the first base layer,
wherein the first base layer includes a first layer having a first electrical conductivity and a second layer having a second electrical conductivity higher than the first electrical conductivity, and
wherein an interval between the second layer and the first emitter layer is larger than an interval between the first layer and the first emitter layer.

2. The compound semiconductor solar cell of claim 1, wherein the first layer is doped with a first doping concentration and the second layer is doped with a second doping concentration higher than the first doping concentration.

3. The compound semiconductor solar cell of claim 2, wherein in the first layer, the first doping concentration is uniform in the thickness direction of the first layer, or increases as the distance from the first emitter layer in the thickness direction of the first layer increases.

4. The compound semiconductor solar cell of claim 3, the first doping concentration is 5e16/cm³ to 5e17/cm³, and the second doping concentration is 5e17/cm³ to 1e18/cm³.

5. The compound semiconductor solar cell of claim 4, wherein in the second layer, the second doping concentration is uniform in the thickness direction of the second layer, or increases as the distance from the first emitter layer in the thickness direction of the second layer increases.

6. The compound semiconductor solar cell of claim 5, wherein the second layer is formed to be thinner than the first layer.

7. The compound semiconductor solar cell of claim 6, wherein the first layer is formed to a thickness of 1 μm to 3 μm, and the second layer is formed to a thickness of 50 nm to 1 μm.

8. The compound semiconductor solar cell of claim 7, wherein each of the first and second layers is formed of a GaAs-based compound semiconductor.

9. The compound semiconductor solar cell of claim 8, wherein the second layer is formed of Al_{0.3}Ga_{0.7}As containing aluminum (Al), and has a higher band gap than the first layer.

10. The compound semiconductor solar cell of claim 9, wherein in the second layer, an aluminum content of the second layer is uniform in the thickness direction of the second layer, or increases as the distance from the first emitter layer in the thickness direction of the second layer increases.

11. The compound semiconductor solar cell of claim 1, wherein the top cell further comprises a first back surface field layer positioned on a back surface of the first emitter layer.

12. The compound semiconductor solar cell of claim 6, wherein the first layer is formed to a thickness of 300 nm to 3 μm, and the second layer is formed to a thickness of 50 nm to 500 nm.

13. The compound semiconductor solar cell of claim 12, wherein each of the first and second layers is formed of GaInP-based compound semiconductors.

14. The compound semiconductor solar cell of claim 13, wherein the second layer is formed of Al_{0.25}Ga_{0.25}In_{0.5}P containing aluminum (Al), and has a higher band gap than the first layer.

15. The compound semiconductor solar cell of claim 14, wherein in the second layer, an aluminum content of the second layer is uniform in the thickness direction of the second layer, or increases as the distance from the first emitter layer in the thickness direction of the second layer increases.

16. The compound semiconductor solar cell of claim 12, further comprising at least one cell formed between the top cell and the back electrode and formed of a compound semiconductor.

17. The compound semiconductor solar cell of claim 16, wherein the at least one cell comprises a window layer, a base layer and an emitter layer sequentially stacked from the top cell toward the back electrode, and the base layer is formed of single layer doped with the first doping concentration, and
wherein in the base layer, the first doping concentration is uniform in the thickness direction of the base layer, or increases as the distance from the emitter layer in the thickness direction of the base layer increases.

18. The compound semiconductor solar cell of claim 17, wherein the at least one cell further comprises a back surface field layer positioned on a back surface of the emitter layer.

19. The compound semiconductor solar cell of claim 17, further comprising a tunnel junction layer positioned between the different cells.

20. The compound semiconductor solar cell of claim 17, wherein the at least one cell is formed of any one selected from a GaAs-based compound semiconductor, a GaInAs-based compound semiconductor, an AlGaAs-based compound semiconductor, an AlGaInAs-based compound semiconductor, and a Ge-based compound semiconductor.
